(19) United States
(12) Patent Application Publication
(10) Pub. No.: US 2005/0056216 A1
(43) Pub. Date: Mar. 17, 2005

(54) Precursor delivery system

(75) Inventor: Ronald Kuse, Fujimi City (JP)

Correspondence Address: FISH & RICHARDSON, PC, 12390 EL CAMINO REAL, SAN DIEGO, CA, 92130-2081, US

(73) Assignee: Intel Corporation

(21) Appl. No.: 10/663,366

(22) Filed: Sep. 15, 2003

(51) Int. Cl. C23C 16/00

(52) U.S. Cl. 118/715

(57) ABSTRACT

A processing system includes a variable volume chamber. A liquid or solid precursor source may be included in the variable volume chamber. The volume of the variable volume chamber may be controlled to provide for a predictable precursor flow to a processing chamber. In some implementations, multiple variable volume chambers may be provided.

### BACKGROUND

Semiconductor devices are generally fabricated using a sequence of processes to form successive device layers on a substrate such as a silicon wafer. In some processes, a layer may be formed by a chemical reaction on the surface of the wafer. These processes include chemical vapor deposition (CVD) processes and atomic layer deposition (ALD) processes.

In performing CVD and ALD processes, a first reactant material (which may be referred to as a precursor) is provided to a processing chamber. FIG. 1 shows an example of a precursor delivery system 100. A solid or liquid source 110 that includes the desired precursor material is placed in a precursor chamber 120. A pressurized carrier gas 130, which is typically a non-reacting gas such as nitrogen or helium, carries sublimed or evaporated precursor 140 to a processing chamber 150.

For a CVD process, a continuous flow of precursor/carrier gas is generally provided to processing chamber 150 until the process is complete. For an ALD process, a pulsing valve 160 is opened for a short amount of time to provide a pulse of reactant and carrier gas to chamber 150. Although the deposition rate using ALD is generally lower than that of CVD processes, ALD may provide improved deposition control and so may be preferred in some situations.

### DESCRIPTION OF DRAWINGS

FIG. 1 is a diagram of a precursor delivery system according to the prior art.

FIG. 2 is a plot of precursor concentration for two ALD pulses using a system such as that shown in FIG. 1.

FIG. 3 is a diagram of an embodiment of a precursor delivery system.

FIG. 4 is a diagram of another embodiment of a precursor delivery system.

Like reference symbols in the various drawings indicate like elements.

### DETAILED DESCRIPTION

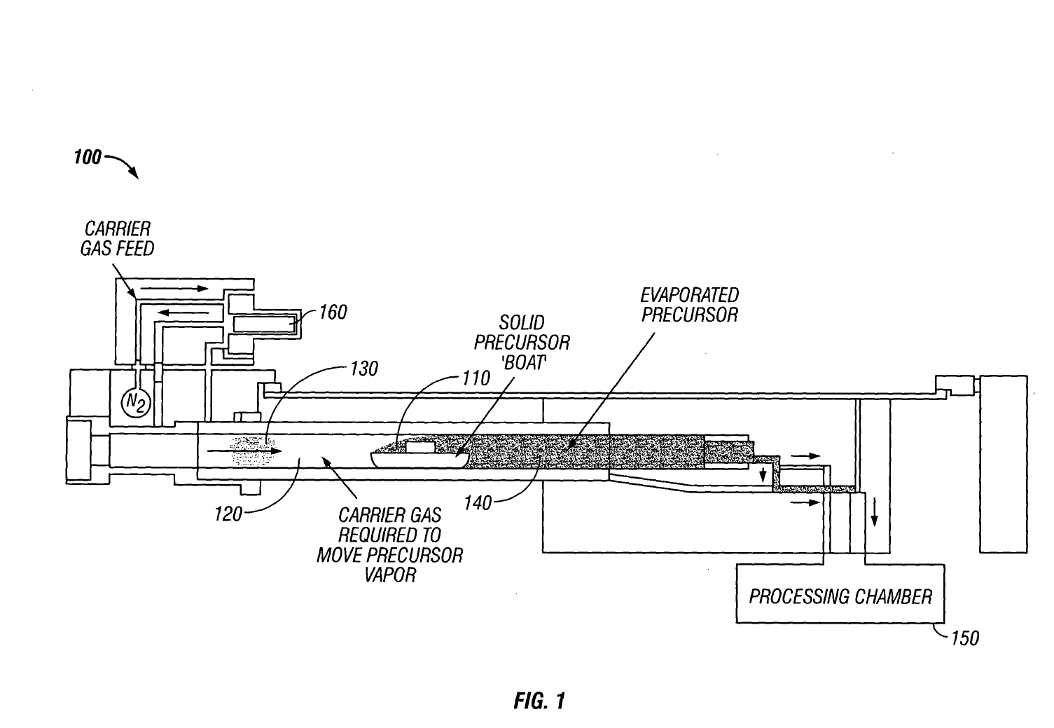

A precursor delivery system such as system 100 of FIG. 1 may not provide sufficient process control for some applications. In particular, when the sublimation rate of a solid precursor material is different than the rate at which the precursor is provided to the processing chamber, the precursor partial pressure will vary over time. For an ALD process, the partial pressure may vary over multiple pulses, as well as over the course of a single pulse. Varying precursor partial pressure may lead to different film growth rates, which may cause non-uniform film thickness. Interfacial and bulk film properties (such as electrical properties) may also be affected by varying precursor partial pressure.

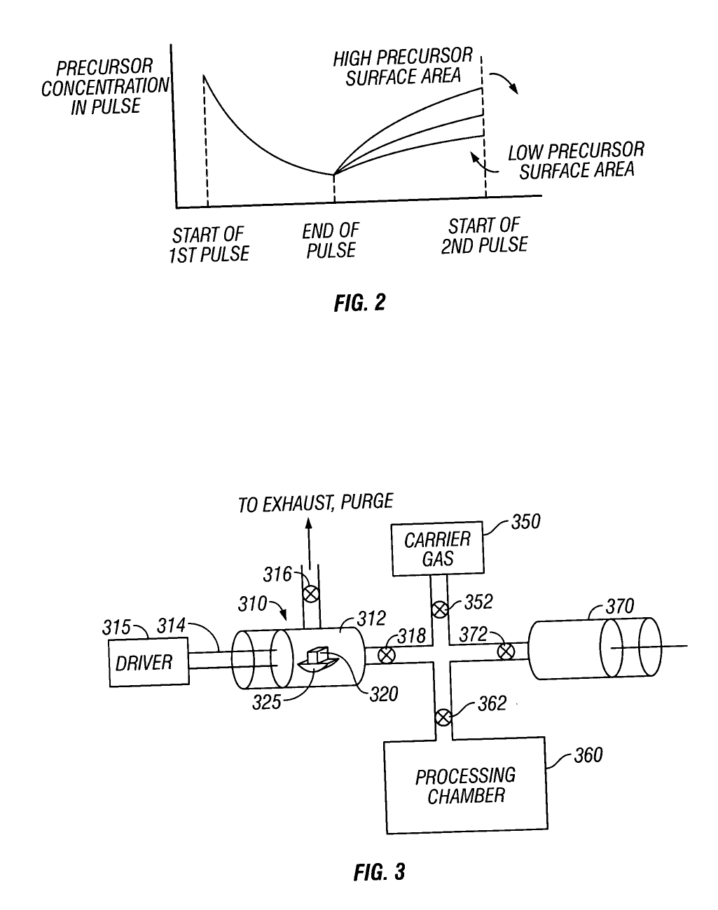

For example, FIG. 2 shows a plot of precursor concentration over a time beginning at the start of a first pulse and ending at the start of a second pulse, for three different configurations of a solid precursor source. Each of the three different configurations correspond to a different precursor surface area, as noted. The three configurations may represent differently configured sources, or may represent the evolution of a particular source over time, where the surface area changes as material sublimes non-uniformly from the surface and/or as precursor chips or powders fuse together.

In the example shown in FIG. 2, the sublimation rate is lower than the rate at which material is being removed from the precursor chamber. At the start of the first pulse, the precursor concentration in the carrier gas is maximum. As the pulse continues, the precursor concentration decreases. As a result, film properties for a layer resulting from the reaction may differ across the wafer. For example, the thickness of a resulting layer may be greater at the leading edge of the wafer (which is exposed to a higher precursor concentration) than at the trailing edge (which is exposed to a lower precursor concentration).

At the end of the first pulse, the flow of precursor material from the chamber is halted, and the precursor concentration begins to recover. As shown, the precursor concentration recovers more rapidly for precursor sources having a greater surface area.

In the example shown in FIG. 2, the time between the pulses is less than the time needed to recharge the precursor chamber to the initial concentration level. At the start of the second pulse, the precursor concentration is different for each of the three configurations, and each corresponds to a lower concentration than that present at the start of the first pulse.

Systems and techniques described herein may provide for improved predictability in precursor concentration. For example, the current systems and techniques may be used to provide a substantially constant precursor concentration. FIG. 3 shows an improved precursor delivery system 300, according to some implementations. A precursor source 320 is in a variable volume chamber 310. Source 320 may be held in a precursor boat 325, which may be configured to hold liquid precursor sources, solid precursor sources, or both. System 300 may also include a carrier gas source 350, although carrier gas is not required.

Chamber 310 includes a body portion 312 and a moveable piston 314, shown in FIG. 3 as circular with an area equal to A. In order to maintain a particular pressure P in chamber 310, a force F=PA is applied to piston 314 (note that this is an approximation for an ideal frictionless piston). While valves 316 and 318 are closed and material is sublimating from source 320, the amount of precursor material in chamber 310 is increasing. Rather than keeping the volume constant and letting the pressure increase (as would occur in a fixed volume system such as system 100 of FIG. 1), the force F is held constant and the volume varied. In order to maintain the force at a desired level, a driver system 315 may be include a pressure detector to determine the force applied to piston 314. If the force applied is different than the desired force, a pressure controller may alter the applied force to be the desired force based on the output of the pressure detector.

In order to provide precursor material to a processing chamber 360, valve 318 may be opened. If the sublimation rate is greater than the rate at which material is provided to chamber 360, the volume of the chamber 310 may be increased to maintain the desired pressure. If the sublimation rate is less than the rate at which material is provided to chamber 360, the volume of chamber 310 may be reduced to maintain the desired pressure.

Chamber 310 may have a maximum volume Vₘₐₓ and a minimum volume Vₘᵢₙ. If the amount of precursor material in chamber 310 increases so that at the desired pressure P the volume of chamber 310 is Vₘₐₓ, any additional sublimed or evaporated precursor material may be vented to another storage area or to an exhaust to maintain the desired pressure. Alternately, the temperature of the precursor source may be reduced to decrease the sublimation rate.

More commonly, the sublimation rate may be low enough that during a process or pulse the amount of precursor material in chamber 310 may decrease so that the volume of chamber 310 is Vₘᵢₙ. Beyond that point, the pressure in chamber 310 would drop below the desired pressure P and the rate of precursor delivery to process chamber 360 would decrease. For processes in which this may occur, one or more additional variable volume precursor chambers such as chamber 370 may be provided.

Multiple chambers may be used in a number of ways. In an implementation in which that sublimation rate is low enough that multiple chambers are necessary to provide precursor material for a single process or pulse, valve 318 may be opened and precursor material provided to processing chamber 360 from chamber 310 until the volume of chamber 310 reaches Vₘᵢₙ (or other volume). Valve 318 may then be closed, and a valve 372 to chamber 370 opened. The process may be continued with additional chambers, or by alternating between chamber 310 and 370.

Multiple chambers may also be used when a single chamber is sufficient to provide material for a particular process or pulse, but when the time between pulses is shorter than the time needed to recharge the chamber sufficiently to provide material for a subsequent pulse. In this situation, a first pulse of precursor material to processing chamber 360 may be provided by chamber 310, while a second pulse of precursor material to processing chamber 360 may be provided by chamber 370. Thus, chamber 310 may “recharge” during the second pulse, and may be used to provide precursor material to processing chamber 360 for a subsequent pulse.

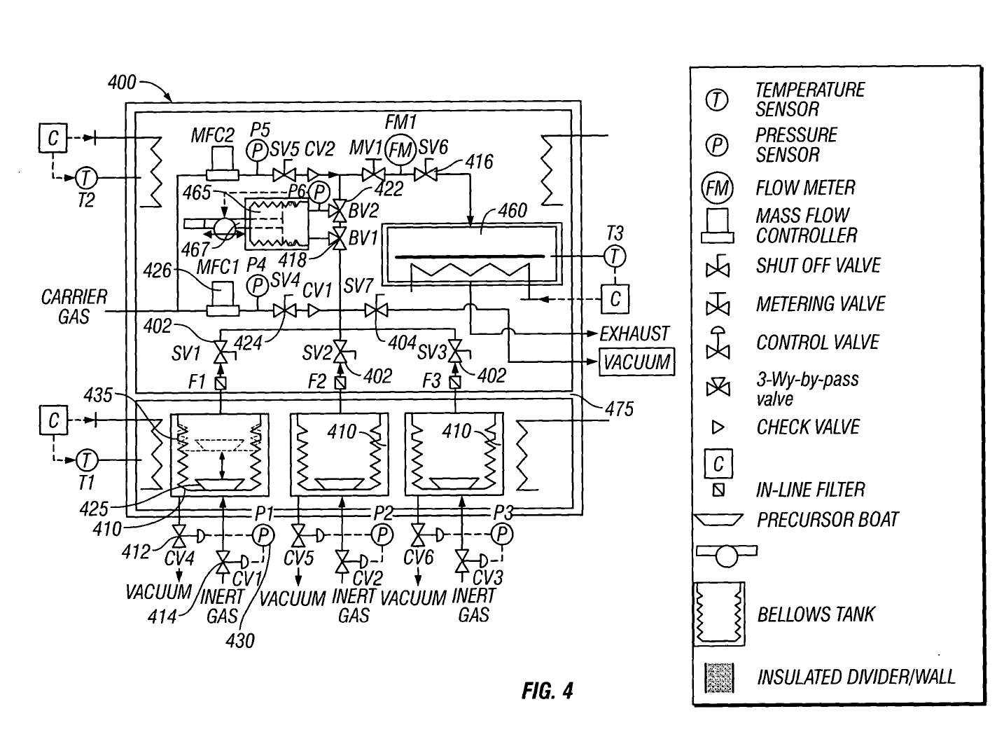

FIG. 3 shows an implementation where a variable volume precursor chamber is implemented using a moveable piston. Other implementations are possible. For example, FIG. 4 shows a system 400 incorporating bellows configurations for one or more variable volume precursor chambers.

System 400 includes three bellows chambers 410, each positioned in an exterior space 435. Each chamber is configured to hold liquid and/or solid precursor material. For example, each chamber 410 may include a precursor boat 425, which may be configured to hold liquid or solid precursor material. A pressure sensor 430 may be provided to monitor the pressure in exterior space 435.

Device processing using system 400 may be accomplished as follows, for an exemplary process using a solid precursor source. A precursor source may be loaded into one or more of bellows chambers 410. Residual gas may then be evacuated from bellows chambers 410 by opening valves 402 and 404 to access a vacuum 406 (e.g., a region evacuated using one or more vacuum pumps).

The precursor source may then be heated to a target temperature. As the temperature increases, precursor material sublimes from the source and the pressure in bellows chamber 410 increases. This increases the exterior pressure on the bellows (e.g., the pressure in exterior space 435). Once the pressure in exterior space 435 exceeds a set point pressure Pₛₑₜ (e.g., a desired precursor pressure for a particular process), a control valve 412 may be opened to reduce the pressure to Pₛₑₜ.

During pulsing, valve 402 is opened, allowing sublimed precursor material to be delivered to processing chamber 460. If the flow rate of precursor material out of bellows chamber 410 is greater than the sublimation rate of the source, the pressure of the bellows will decrease and the bellows will contract. As a result, the pressure in exterior space 435 will begin to decrease. A control valve 414 may be opened to connect exterior space 435 to a gas source, in order to maintain the pressure of exterior space 435 at Pₛₑₜ.

Precursor material may be provided to processing chamber 460 either as a pure vapor or mixed with an inert carrier gas. In order to provide the precursor material as pure vapor, all intervening valves between valve 402 and processing chamber 460 may be opened. Bellows chamber 410 may provide a substantially constant back pressure so that the flow rate of precursor material is substantially constant during the pulse.

Alternately, the precursor material may first be provided to a bellows tank 465 via a valve 418. After bellows tank 465 is brought to a desired pressure, valve 418 may be closed. Valve 422 may be opened, and bellows tank 465 may be compressed using a drive piston 467. The exit pressure of the precursor material may be monitored, and the speed at which drive piston 467 compresses bellows tank 465 controlled. This implementation may provide a particular benefit for high concentration, short duration pulses.

To provide precursor material mixed with a carrier gas to processing chamber 460, a valve 424 to a mass flow controller 426 in communication with a carrier gas source may be opened. Controller 426 may control the flow rate of the carrier gas as desired. The carrier gas source may also be used to purge portions of system 400 between pulses.

In some implementations, bellows chambers 410 may be thermally isolated from processing chamber 460, so that the precursor temperature can be different than the processing temperature. However, in order to prevent condensation of precursor vapor in system 400, the temperature of processing chamber 460 may need to be kept higher than the temperature of bellows chambers 410.

The thermal isolation may include providing a sufficient thermal impedance (resistance to heat flow) between bellows chambers 410 and processing chamber 460 so that a temperature of the bellows chamber 410 may be maintained at a first desired temperature, while the temperature of the processing chamber may be maintained at a second desired temperature different than the first desired temperature by a temperature differential.

The thermal impedance may be provided by using materials of low thermal conductivity between bellows chambers 410 and processing chamber 460. For example, bellows chambers 410 and processing chamber 460 may be separated by a thermal isolation region 475 made from a material of low thermal conductivity. Additionally, the thermal impedance of fluid lines between bellows chambers 410 and processing chamber 460 may be sufficient to obtain the desired temperature differential.

In some implementations, precursor material is adsorbed on a substrate surface, and an oxidizer subsequently provided to processing chamber 460 to react with the precursor material. Fluid lines for oxidizer materials are not shown in FIG. 4, but may be provided. Possible oxidants include water vapor, oxygen, ozone, hydrogen peroxide, metal alkoxides, or other oxidizers. Similarly, in some implementations, the precursor material is to react with a nitrogen-containing molecule such as ammonia to produce a metal nitride.

A number of implementations have been described. Nevertheless, it will be understood that various modifications may be made without departing from the spirit and scope of the invention. For example, different numbers of variable-volume precursor chambers may be used. Although implementations with chambers incorporating pistons and bellows have been shown, other implementations are possible. For example, some implementations may use chambers incorporating conducting or non-conducting flexible membranes, where the chamber pressure may be controlled using (for example) an external pressure, an electromagnetic field, or other control mechanism. Accordingly, other implementations are within the scope of the following claims.

1. A semiconductor processing system, comprising:
a variable volume chamber to provide a material for a semiconductor process;
a pressure detector to detect a parameter indicative of a pressure of the variable volume chamber and to produce an output indicative thereof; and
a pressure controller in communication with the pressure detector and the variable volume chamber, the pressure controller to apply a force to the variable volume chamber based on the output of the pressure detector.

2. The system of claim 1, wherein the pressure controller is to apply the force to keep the pressure of the variable volume chamber substantially constant.

3. The system of claim 1, further including a processing chamber, and wherein the variable volume chamber is to provide a precursor material to the processing chamber.

4. The system of claim 3, wherein the precursor material is to react with another material in the processing chamber.

5. The system of claim 1, wherein the semiconductor process is a chemical vapor deposition process.

6. The system of claim 1, wherein the semiconductor process is an atomic layer deposition process.

7. The system of claim 1, wherein the variable volume chamber comprises a bellows.

8. The system of claim 7, wherein the bellows is included in a pressurization region.

9. The system of claim 8, wherein the pressure controller comprises a gas source to selectively communicate with the pressurization region.

10. The system of claim 9, wherein the gas source is to selectively communicate with the pressurization region when the pressure of the pressurization region is below a desired pressure.

11. The system of claim 8, wherein the pressure controller comprises a vacuum source to selectively communicate with the pressurization region.

12. The system of claim 11, wherein the vacuum source is to selectively communication with the pressurization region when the pressure of the pressurization region is above a desired value.

13. The system of claim 1, wherein the variable volume chamber comprises a piston.

14. The system of claim 13, wherein the parameter indicative of the pressure is a force on the piston.

15. The system of claim 1, further including another variable volume chamber.

16. A method, comprising:
transmitting a material from a variable volume chamber to a semiconductor processing chamber;
during the transmitting, detecting a parameter indicative of a pressure in the variable volume chamber; and
changing the volume of the variable volume chamber based on the detecting.

17. The method of claim 16, wherein changing the volume of the variable volume chamber based on the detecting comprises increasing the volume of the variable volume chamber if the parameter indicates that the pressure is greater than a desired pressure.

18. The method of claim 16, wherein changing the volume of the variable volume chamber based on the detecting comprises decreasing the volume of the variable volume chamber if the parameter indicates that the pressure is less than a desired pressure.

19. The method of claim 16, wherein the detecting comprises detecting a pressure of a pressurization region exterior to the variable volume chamber.

20. The method of claim 19, wherein changing the volume of the variable volume chamber comprises increasing the pressure of the pressurization region.

21. The method of claim 19, wherein changing the volume of the variable volume chamber comprises decreasing the pressure of the pressurization region.

22. The method of claim 16, wherein changing the volume of the variable volume chamber comprises applying a force to a piston.

23. A chemical delivery system, comprising:
a variable volume chamber having an outlet, the outlet to transport a material from an interior region of the variable volume chamber to another region;
a pressure detector to detect a parameter indicative of a pressure of the variable volume chamber and to produce an output indicative thereof; and
a pressure controller in communication with the pressure detector and the variable volume chamber, the pressure controller to apply a force to the variable volume chamber based on the output of the pressure detector.

24. The system of claim 23, wherein the pressure controller is to apply the force to keep the pressure of the variable volume chamber substantially constant.

25. The system of claim 23, wherein the variable volume chamber comprises a bellows.

26. The system of claim 25, wherein the bellows is included in a pressurization region.

27. The system of claim 26, wherein the pressure controller comprises a gas source to selectively communicate with the pressurization region.

28. The system of claim 26, wherein the pressure controller comprises a vacuum source to selectively communicate with the pressurization region.

29. The system of claim 23, wherein the variable volume chamber comprises a piston.

30. The system of claim 23, further including another variable volume chamber.
